(19) United States
(12) Patent Application Publication
(10) Pub. No.: US 2012/0192952 A1
(43) Pub. Date: Aug. 2, 2012

(54) THREE-DIMENSIONAL MICROFLUIDIC SYSTEMS

(75) Inventors: Wei Shen, Victoria (AU); Xu Li, Victoria (AU); David Robert Ballerini, Victoria (AU); Junfei Tian, Victoria (AU)

(73) Assignee: Monash University, Victoria (AU)

(21) Appl. No.: 13/384,848

(22) PCT Filed: Jul. 20, 2010
(86) PCT No.: PCT/AU2010/000922

§ 371 Date: Apr. 4, 2012

(30) Foreign Application Priority Data
Jul. 20, 2009 (AU) 2009903382

(51) Int. Cl. B81B 1/00; B81B 3/00

(52) U.S. Cl. 137/1; 137/833; 137/825

(57) ABSTRACT

A three-dimensional microfluidic system including: at least one hydrophilic thread along which fluid can be transported through capillary wicking; and at least one hydrophobic substrate for supporting the hydrophilic thread. A method of transporting and mixing a plurality of fluids within a microfluidic system including at least two hydrophilic threads and a hydrophobic substrate having at least two zones, each of the hydrophilic threads supported on a different hydrophobic substrate zone, including: delivering each said fluid to a different hydrophilic thread; and bringing the at least two hydrophilic threads into contact to cause mixing of the fluids.

### FIELD OF THE INVENTION

The present invention is directed to three-dimensional microfluidic systems.

### BACKGROUND OF THE INVENTION

Microfluidic systems utilising microfluidic channels are generally limited to fluid flows in two dimensions along the plane of the surface of the substrate supporting the channels. The concept and design of the microfluidic systems is to use capillary channels defined by the physical or chemical barriers to control the flow path of fluids. There are however advantages in being able to have microfluidic channels running in three dimensions, since three dimensional microfluidic systems can substantially reduce the size of microfluidic devices. Also, there is a great advantage of taking a different approach of fabricating microfluidic channels to form microfluidic devices without having to put physical and chemical barriers on the surface of the substrate supporting the channels.

In Honkai Wu, Teri W. Odom, Daniel T. Thui and George M. Whitesides, J. Am. Chem. Soc. 2003, 125, 554-559 “Fabrication of complex three-dimensional microchannel systems in PDMS”, such a three-dimensional microfluidic system is described. This paper described a system which utilises channels formed from polydimethlsiloxame (PDMS) which can be fabricated into complex geometries thereby allowing the flow of fluids in more than one plane. The fabrication of such systems is however, complex, and the use of PDMS limits the types of solution that can be passed through the channels. In Martinez A. W.; Phillips S. T. and Whitesides GM. PNAS, 2008, 105, 19606-19611 “Three-dimensional microfluidic devices fabricated in layered paper and tape”, a three-dimensional paper-based microfluidic device is described. This paper described the fabrication of the three-dimensional device using a laminated structure of paper and tape. The microfluidic channel pattern was fabricated using photolithography and PDMS. The device fabricated in this manner utilizes the principle of defining physical barrier in a porous substrate; the devices are therefore rigid. For long fluidic channels, a relatively large volume of liquid is required, since the three-dimensional channels must be filled with fluid.

### SUMMARY OF THE PRESENT INVENTION

It is therefore an object of the present invention to provide a three dimensional microfluidic system that provides a novel barrier-free fluid transportation concept and overcomes at least one of the disadvantages of known systems.

With this in mind, according to one aspect of the present invention, there is provided a three dimensional microfluidic system including at least one hydrophilic thread along which fluid can be transported through capillary wicking, at least one hydrophobic substrate for supporting the hydrophilic thread. The thread may for example be sewn into or wound around or braided with the hydrophobic substrate depending on the physical characteristics of the substrate. It is envisaged that more than one hydrophilic thread be utilised. Alternatively or in addition, more than one hydrophobic substrate may be used.

According to a preferred embodiment, a plurality of hydrophilic threads may be supported on the at least one hydrophobic substrate, wherein said threads are separate from each other. This enables different fluids to be transported along different threads without any mixing occurring, even though the threads may overlap without contacting. Alternatively, a plurality of hydrophilic threads may be supported on the at least one hydrophobic substrate, wherein at least one pair of said threads are in contact with each other. This allows for a degree of mixing to occur between fluids transported on the different threads that are in contact.

The hydrophobic substrate may be made from any one of a variety of different materials including, but not limited to, polymer, metal ceramic or composites of these materials.

The hydrophobic substrate may preferably be a continuous film through which the hydrophilic thread is woven. Alternatively, the hydrophobic substrate may be a woven sheet though which the hydrophilic thread is interwoven. In another preferred embodiment, the hydrophobic substrate may be a hydrophobic thread about which a said hydrophilic thread is twisted. It is envisaged that the hydrophobic substrate may be a gel or wax for supporting the hydrophilic thread passing therethrough.

The hydrophilic thread may be formed from any hydrophilic material. According to a preferred embodiment of the invention, the hydrophilic thread may be formed from cellulose material. The hydrophilic thread is preferably formed from a continuous filament of hydrophilic material. Alternatively, the hydrophilic thread may be a formed from a discontinuous line of hydrophilic powder. The hydrophilic thread may have a diameter of between 1 mm and 1 nm. Alternatively, the hydrophilic thread may have a cross-section of variable diameter to thereby allow control of the fluid flow rate of the fluid transported along the thread.

According to another aspect of the present invention, there may be provided a three-dimensional microfluidic system including at least one hydrophobic thread supported on a hydrophilic substrate, wherein said fluid is transportable along the thread by capillary wicking. The fluids that can be transported along a hydrophobic thread include non-aqueous fluids such as hydrocarbon fluids, oils and other low surface tension organic fluids.

Preferably the system further includes a switch means for allowing or preventing fluid flow along the at least one hydrophilic thread. The switch means may include at least one hydrophobic segment on the at least one hydrophilic thread and means for bypassing the hydrophobic segment and allowing fluid flow. The bypass means may include a looped hydrophilic thread. Alternatively the bypass means may include a bridging hydrophilic thread.

According to a further aspect of the present invention, there is provided a method of transporting at least one fluid within a microfluidic system including at least one hydrophilic thread, including delivering the fluid to an end of the hydrophilic thread, the fluid being transported along the thread through capillary wicking. Preferably, a plurality of fluids may be transported without mixing through the microfluidic system, as each said fluid is delivered to a different hydrophilic thread, the threads being separate from each other. Alternatively, a plurality of fluids may be transported and mixed through the microfluidic system, by delivering each said fluid to a different hydrophilic thread, the threads being in contact with each other.

According to yet another aspect of the present invention, there is provided a method of detecting a fluid sample within a microfluidic system including at least one hydrophilic thread, including delivering said fluid sample to an end of the hydrophilic thread for transportation by capillary wicking therealong, at least part of the thread forming a sample detection zone.

According to yet another aspect of the present invention, there is provided a method of transporting and mixing a plurality of fluids within a microfluidic system including at least two hydrophilic threads and a hydrophobic substrate having at least two zones, each of the hydrophilic threads supported on a different hydrophobic substrate zone, including: delivering each said fluid to a different hydrophilic thread; and bringing the at least two hydrophilic threads into contact to cause mixing of the fluids. Preferably the hydrophobic substrate zones are folded together bringing the at least two hydrophilic threads into contact.

The three dimensional microfluidic system according to the present invention may be used in a large number of different applications. The invention may be built within other materials such as woven, non-woven, powder, gel, wax and so on to form microfluidic sensors utilizing colorimetric and non-colorimetric detection principles. The present invention can for example be used to perform Enzyme-linked immunosorbent assay (ELISA) like tests, electrophoresis and chromatographic analyses as well as other more complex reactions and tests. The hydrophilic threads may be used to transport and detect a wide range of liquids including hydrocarbons.

The present invention can therefore be used in applications in bio-assays of different bio-fluids, or in environmental testing of, for example, water quality. Because the microfluidic system can be built into other materials, it has many personal care and military applications as an integrated detection system within, for example, the fabric of the clothes of the civilian or military wearer. The present invention can be used in isolated or combined with any other analytical instrument.

The three-dimensional microfluidic systems according to the present invention have many advantages. It preferably allows for a variety of different fluids to be transported unlike previous systems based on PDMS and other physical barriers where the fluid being transported can physically or chemically react with or swell the barrier. It preferably only requires a relatively small volume of sample fluid, unlike other diagnostic or detection devices. It has been found for example that fluid volumes of as low as 0.1 micro litres can provide usable results. The systems can preferably be made very compact thereby allowing a high density of circuitry in the devices using the present invention. The production costs may be relatively low due to ease of manufacture and has high design flexibility. These systems could therefore be made as part of a disposable product. A variety of different fluids may be transported, and the fluid flow can preferably be controlled to allow for mixing of fluids or controlling the fluid flow rate by, for example, varying the cross-section of the thread. The present invention can also preferably be readily integrated to operate with different switches and flow control devices.

In addition to the requirement for control of flow in microfluidic devices, a need exists for the mixing of reagents and samples. Complex detection chemistries often involve multiple steps and chemical intermediates, and this calls for the ability to mix liquids together onboard lab-on-a-chip devices. For example, rapid mixing is necessary in many microfluidic systems used for biochemical analyses, such as those involving enzymatic reactions.

### BRIEF DESCRIPTION OF THE DRAWINGS

It will be convenient to further describe the invention with respect to the accompanying figures which illustrate preferred embodiments of the three dimensional microfluidic system according to the present invention. Other embodiments of the invention are possible, and consequently, the particularity of the accompanying figures is not to be understood as superseding the generality of the preceding description of the invention.

In the drawings:

FIG. 1 shows a first example of three-dimensional microfluidic system according to the present invention;

FIG. 2 shows a second example of the three-dimensional microfluidic system according to the present invention;

FIG. 3 shows a third example of the three-dimensional microfluidic system according to the present invention;

FIG. 4 shows a fourth example of the three-dimensional microfluidic system according to the present invention; and

FIG. 5 shows a fifth example of the three-dimensional microfluidic system according to the present invention.

FIG. 6 shows a sixth example of the three-dimensional microfluidic system according to the present invention.

FIG. 7 shows a seventh example of the three-dimensional microfluidic system according to the present invention.

FIG. 8 shows an eighth example of the three-dimensional microfluidic system according to the present invention.

FIG. 9 shows a ninth example of the three-dimensional microfluidic system according to the present invention.

FIG. 10 shows a tenth example of the three-dimensional microfluidic system according to the present invention.

FIG. 11 shows an eleventh example of the three-dimensional microfluidic system according to the present invention.

FIG. 12 shows a twelfth example of the three-dimensional microfluidic system according to the present invention.

FIG. 13 shows a thirteenth example of the three-dimensional microfluidic system according to the present invention.

FIG. 14 shows a fourteenth example of the three-dimensional microfluidic system according to the present invention.

FIG. 15 shows a fifteenth example of the three-dimensional microfluidic system according to the present invention.

FIG. 16 shows a sixteenth example of the three-dimensional microfluidic system according to the present invention.

### DETAILED DESCRIPTION OF THE PRESENT INVENTION

Thread conducts the flow of liquids via capillary action, with the space between the cellulose fibres of the thread forming capillary channels. Blockage of these channels with glues or waxes can be used strategically to disable the capillary flow of liquids past a certain point in a thread. Using this effect it is possible to simply create flow control devices with thread.

As shown in the following examples, thread can be used to construct on/off functional switches which allow the user to enable or disable liquid flow in thread-based microfluidic devices, thus enhancing the possibilities for the fabrication of low-cost thread-based reactors. Different reagents in multi-step reactions can be introduced into reaction zones simultaneously or separately by simply activating or deactivating switches.

Thread-based devices can also be built as selectors which allow users to direct the samples or reagents they desire to a required location. Moreover, thread can be used as a controllable mixer which is useful when a requirement to mix samples and reagents together at a specific time exists. All of these new and simple types of thread-based microfluidic device components are very low cost and can be easily fabricated without special laboratory equipment, and are therefore suitable for use in underdeveloped areas, remote regions or potentially as point-of-care products globally.

Thread channels can be blocked using commercially available cyanoacrylate-based fast acting adhesive to selectively inhibit liquid flow along a thread. With the application of adhesive or glue, no fluid penetration past the glue-sealed segment is possible. The glue completely blocks the inter-fibre channels within the thread. Also, the glue can be employed to firmly fix thread onto polymer film. These blocking and adhesive characteristics allow switches to be built into thread-based microfluidic devices.

Polypropylene polymer films can be used to support threads and fabricate fold, wedge and pull tab type switches (all of which are detailed below).

The following examples illustrate the operation of the three dimensional microfluidic system in a variety of different situations. The initial five examples illustrate the principles of operation of the three-dimensional microfluidic systems according to the present invention. The remaining examples illustrate embodiments of the invention having flow control arrangements.

### Example 1

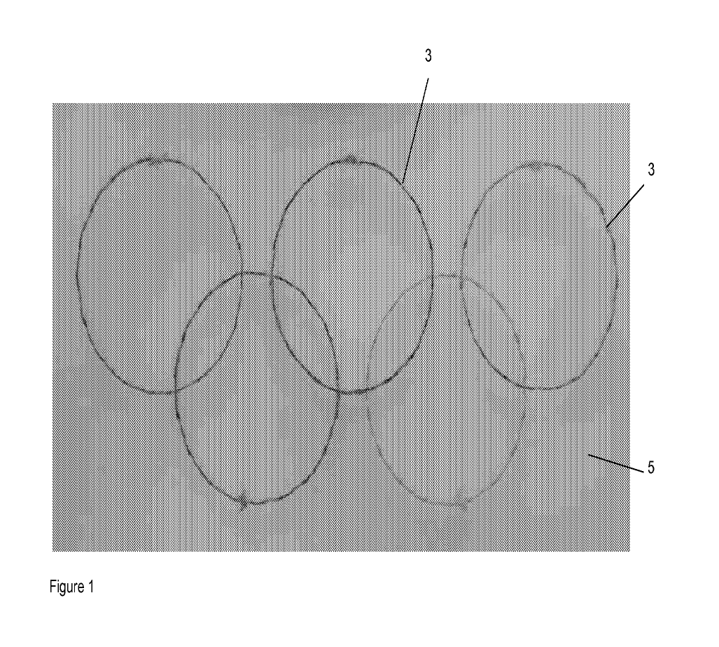

In one embodiment of the invention as shown in FIG. 1, a thread 3 of cotton fibre was treated with a plasma (K1050X) plasma asher (Quorum Emitech, UK) for 5-50 seconds at the intensity of 10-50 W) to increase its hydrophilicity. The treated thread 3 showed no visible mark or colour change. Several pieces of treated thread 3 were then sewn through a polymer film 5 in a pattern shown in FIG. 1 where there are several overlapping circles. This is a three-dimensional pattern where several pieces of thread cross one another, their stitches passing each other from above and below the polymer film; they therefore do not have contact. These threads define the capillary passageways without the need of a barrier. When fluids were introduced on to different threads, they travel along the thread by capillary effect. Because of the three-dimensional structure, the microfluidic system device allowed the fluids to travel independently without mixing. Such a microfluidic system can be built in multilayers to form a complex fluid transport device. Such a microfluidic system can be used to transport a wide range of fluids, including hydrocarbons, which cannot be transported by microfluidic systems with PDMS barriers.

### Example 2

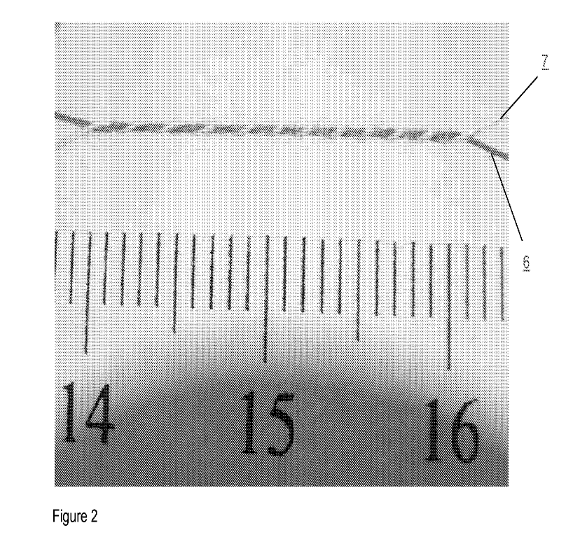

The second embodiment of the invention as shown in FIG. 2, illustrates how a hydrophilic thread can transport a fluid sample without being woven or sewn into a supporting substrate. When one hydrophilic thread 6 forms a braid with a hydrophobic thread 7, the fluid only travels along the hydrophilic thread 6. FIG. 2 shows a braid of two cotton threads with one treated with plasma 6 and the other not treated 7. Hydrophilic characteristics of the thread are provided by the plasma treatment. Fluid introduced onto the treated thread 6, only traveled along that hydrophilic thread 6. This has a practical benefit in that the present invention can be incorporated within textiles used for clothing as well as other applications.

When using a sewing machine to sew thread through textile, some machines use two threads, one which goes with the needle, and the other which comes from the bottom. If one of these threads is hydrophilic and the other hydrophobic, liquid will only transport through the hydrophilic thread. Or, a pattern can be sewn where one thread (hydrophobic) holds the other (hydrophilic), but with only hydrophilic thread transporting fluid. The hydrophobic thread that holds the hydrophilic thread will not transport fluid. Alternatively, a hydrophilic thread in a rope can be used to transport or detect a fluid sample, but other threads in the rope will merely be used to provide strength, not transporting fluid samples.

### Example 3

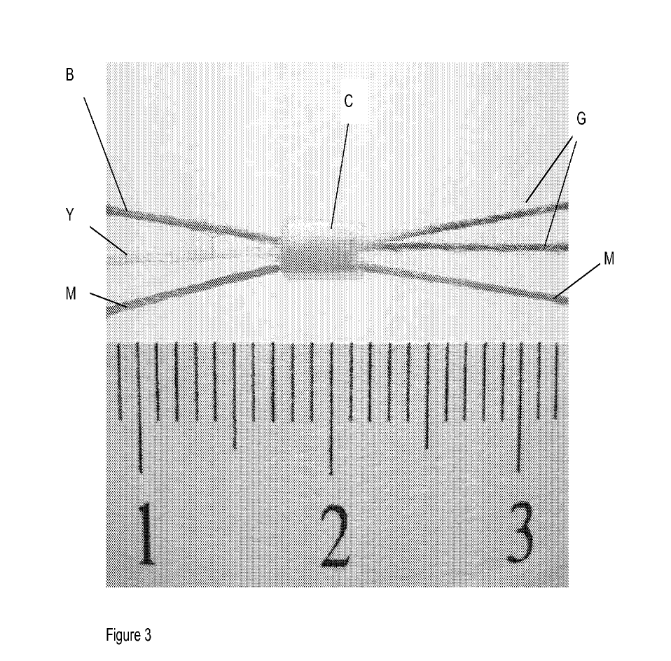

The third embodiment of the invention as shown in FIG. 3, illustrates how a microfluidic system according to the present invention can be made using hydrophilic threads to mix different fluids during fluid transport along the threads. FIG. 3 shows, on the left, three plasma treated threads B, Y, M taking fluids of three different colours; with the uppermost thread transporting a blue fluid B, the middle thread transporting a yellow fluid Y, and the lowermost thread transporting a magenta fluid M. The uppermost and middle threads were braided at a central mixing area C whereas the lowermost thread is not. The fluids of the two braided threads B, Y mixed to form green fluid G to the right of the central mixing area C, whereas the magenta fluid transported in the lowermost thread M did not undergo mixing as it was not braided with the other threads.

### Example 4

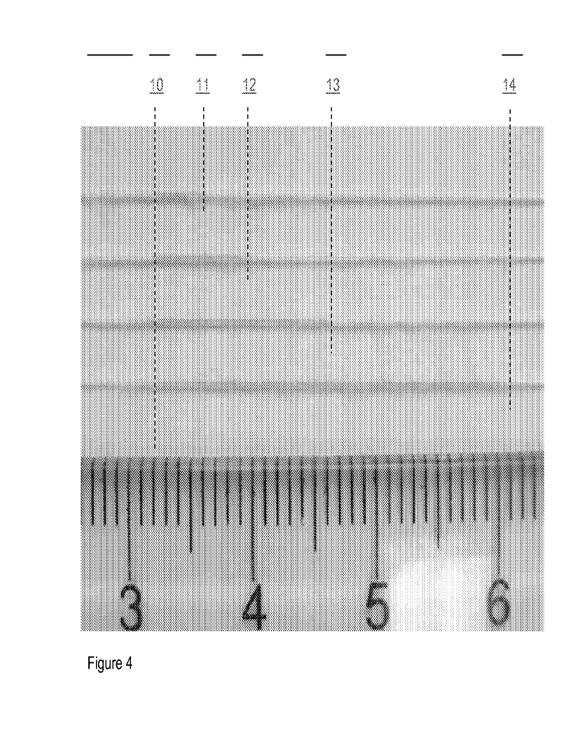

The fourth embodiment of the invention as shown in FIG. 4, illustrates how a hydrophilic thread can be used to make a sample detector. The amount (in volume) of the liquid introduced onto a thread results in a length of wicking that is proportional to the volume added. The colour change on a single stitch of thread due to the passage of fluid along its length is sufficient to deliver visual detection. FIG. 4 shows a series of hydrophilic threads where 0.1, 0.2, 0.4 and 0.8 micro Litres of colour fluid were respectively introduced onto each plasma treated thread, from the topmost to lowermost thread. The lengths of the thread that have changed colour due to the transportation of the fluid along the thread are almost proportional to the fluid volumes introduced. The point where the fluid was introduced on each thread is labelled 10 in FIG. 4. The uppermost thread had 0.1 micro Litre of fluid introduced into it. The fluid traveled to the point marked 11 in FIG. 4. The point marked 12 corresponds to the point where 0.2 microLitre of fluid was transported. Similarly, point 13 indicates where 0.4 micro Litre of fluid traveled to and point 14 indicates where 0.8 micro Litre of fluid traveled to. This proportionality means that the colour density of the liquid on the thread is not affected by how much volume of each sample is added onto a thread. The colour density of the stain will be the same, since the amount of dye per unit length of the stained thread is the same. Therefore even without an accurate liquid handling device, good analytical results can be obtained.

### Example 5

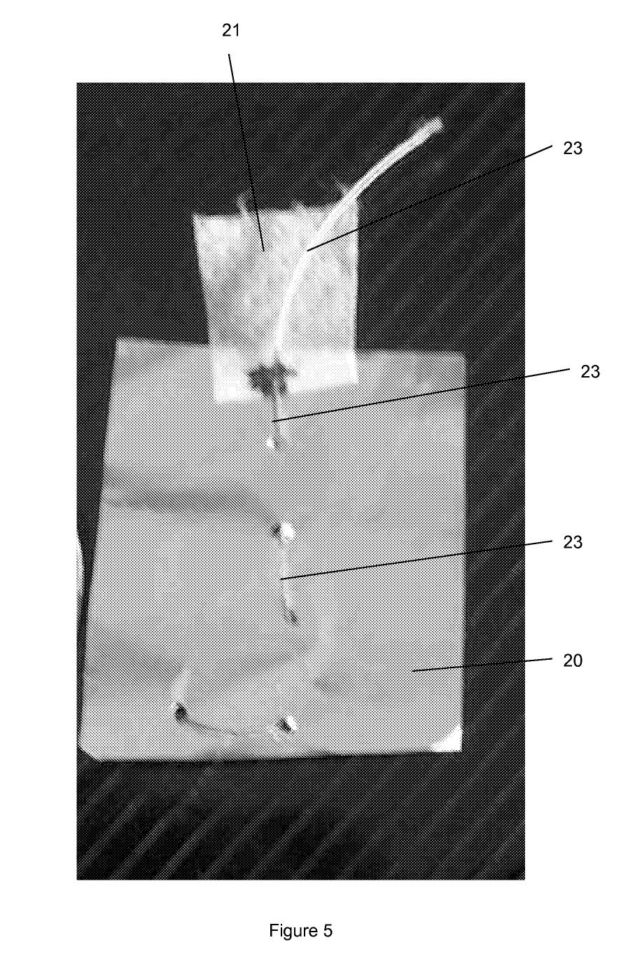

The fifth embodiment of the invention as shown in FIG. 5, illustrates how a hydrophilic thread can be used to construct microfluidic sensors with other materials including, but not restricted by, paper, textile and other woven, non-woven material, powdery, gel, wax and a wide range of other materials. In FIG. 5 there is shown fluid transported through an aluminium foil substrate 20, with a piece of paper 21 being used as a detector to show the arrival of the fluid. In this arrangement, the hydrophilic thread 23 is used as the liquid transport path and paper 21 is used as the colour-revealing detector. Colour change on the paper can occur on a larger area than on a single stitch of thread and can therefore offer a stronger signal. To do so, the indicator or the sample can be deposited on the piece of paper 21, and the thread 23 can then be used to transport said sample or indicator. Therefore, when the sample travelling along the thread sees the indicator on paper (or when the indicator travelling along the thread sees the sample on the paper), a detectable signal can be collected.

### Example 6

### Knot Style Switch

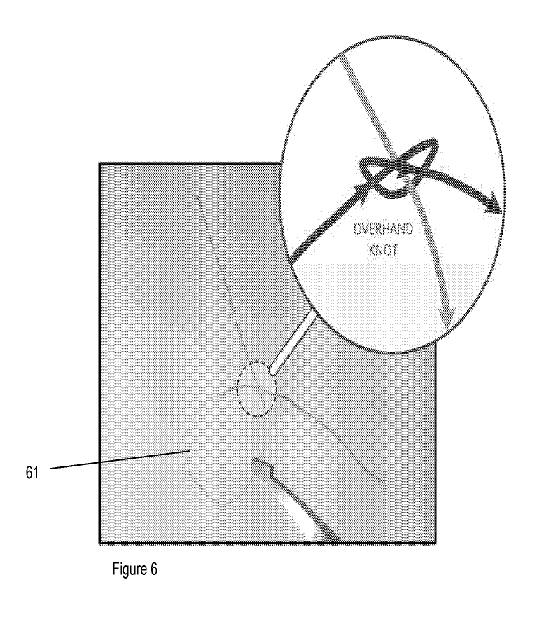

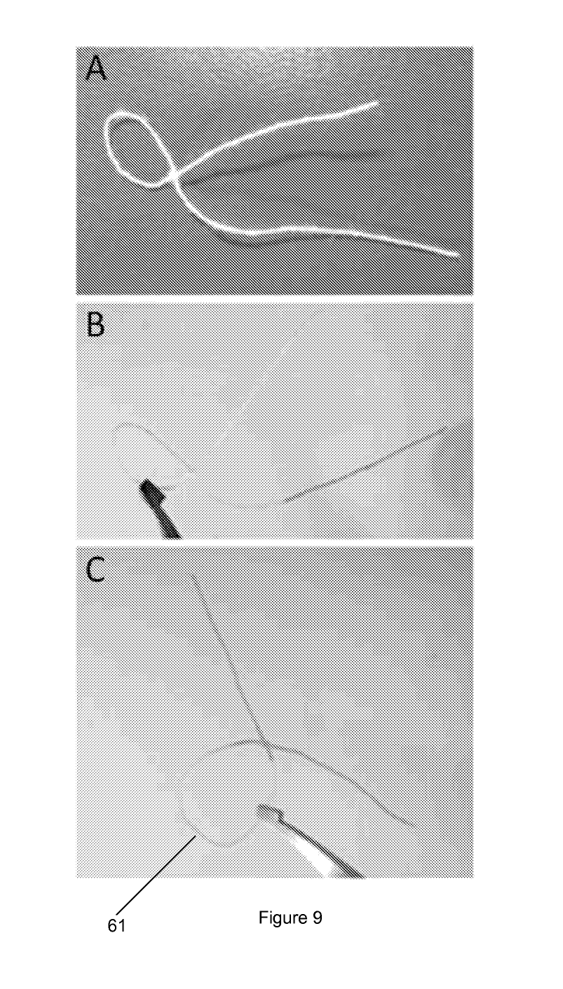

The sixth embodiment illustrates how a knot on a single piece of thread can be used to create a basic on/off flow control mechanism, referred to as a switch. This is shown in FIGS. 6 and 9.

The insert to FIG. 6 illustrates how to tie a simple overhand knot. An overhand knot with a draw loop is tied in a thread loosely such that it can slide along the length of the thread. A section of the draw loop has a small hydrophobic region created by wetting the thread with a small amount of fast drying adhesive (e.g. “Supa Glue”) which effectively blocks the capillary channels between the cellulose fibres of the thread thus blocking fluid flow in the thread. The knot is then slid and placed over this region so that flow can not occur. The switch is now in the “off” position. When the knot is slid away from the blocked region, fluid is allowed to flow through the length of the thread. The blocked channel area 61 remains unstained despite the movement of magenta ink along the rest of the thread.

In FIG. 9, diluted inkjet magenta ink was used to examine the on/off flow along the knotted switch. The switch can be placed in the “off” position by placing the knot over the adhesive-blocked region, causing the ink to stop penetrating when it reaches the blocked region. As illustrated in FIG. 9C, after sliding the knot away from the blocked region 61, the ink flows across the knot and through the length of the thread, while the blocked region remains unwet by the fluid. The principal advantage of such a design is in its simplicity. No films or supports are required for this type of switch, it can be produced from a single piece of thread.

### Example 7

### Wedge Style Switch

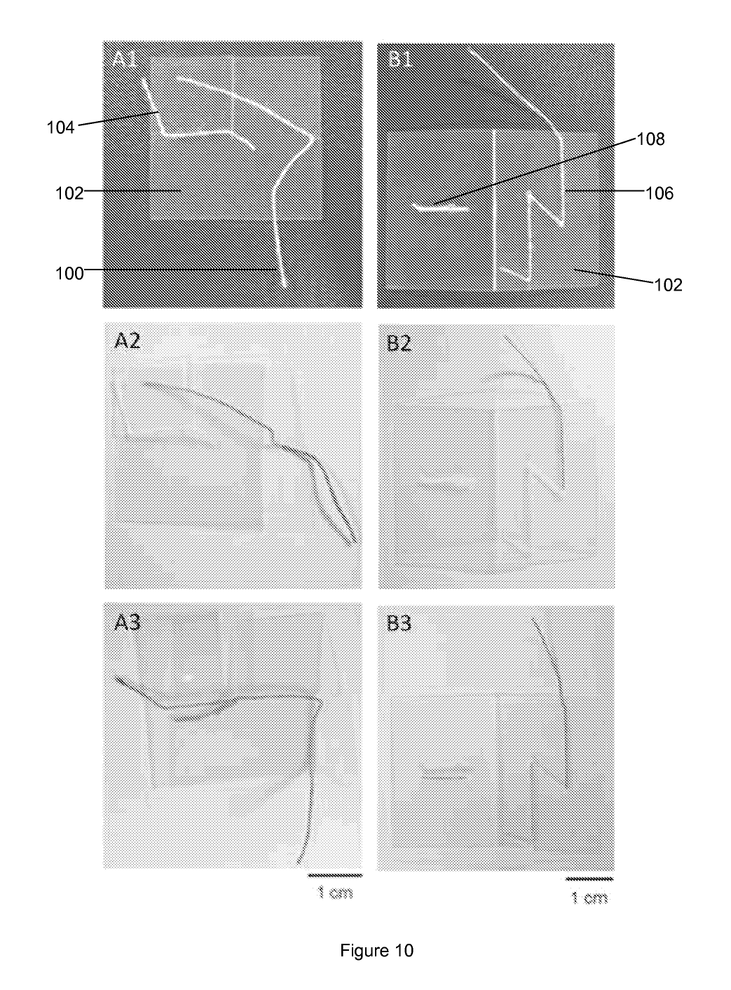

A “wedge” film enabled switching device for binary style flow control is shown in FIGS. 10A1, 10A2 and 10A3. The device is constructed by cutting two small slits (˜5 mm) directly opposite each other and centrally located on opposing edges of a rectangular polymer film. A third slit is then cut in between and perpendicular to the first two and also centrally on the rectangles edge, penetrating inwards approximately half of its width. A thread of the desired length can then be wedged into each of the two outer slits. The free end of one of these two threads can then be tightly wedged into the central slit, while the other thread is only loosely placed in the central slit above the first.

FIG. 10A1 shows the unused wedge type switch in the open/off position. The partly wetted wedge switch in FIG. 10A2 remains open and disables ink flow. FIG. 10A3 shows a closed switch conducting ink flow. Flow is conducted between two threads simply by pulling the thread on the right down 100 and wedging it within a slit in the polymer film 102, where it is locked in contact with the thread on the left 104. Liquid (diluted magenta ink) flows can now easily jump between these threads, creating a continuous flow path. This design can be constructed without much equipment, for example, only thread, scissors and a piece of plastic film is necessary.

### Example 8

### Folding Style Switch with Bridge

A fold enabled device is shown in FIGS. 10B1, 10B2 and 10B3. The device is constructed from a rectangular polymer film, folded into two smaller rectangles of equal area. On one side of the fold, a thread 106 was stitched into the film 102 running parallel with the crease line of the fold, but with a “z” shaped kink in the centre, its ends fixed to the film by being wedged into small slits. The diagonal section of the “z” shape, which is on the exterior surface of the folded device, was then blocked using adhesive to prevent flow. On the opposing side of the film, a small bridge 108 was sewn which was perpendicular to the fold line and directly opposite the centre of the “z” shape.

FIG. 10B1 shows the unused fold type switch in the open/off position. The partially wetted fold switch in FIG. 10B2 remains open and disables ink flow. FIG. 10B3 shows a reopened fully wetted fold switch after it was used to transport ink flow. This microfluidic switch device is activated by the film being folded onto itself. This brings threads 106, 108 on opposing sides into contact with each other. The small thread section 108 on the left acts as a bridge allowing fluid to jump between different sections of a partially blocked thread 106 on the right. Additionally, other porous materials such as textile and paper can be used to act as bridges to allow on/off flow control on the thread.

### Example 9

### Pull-Tab Activated Style Switches

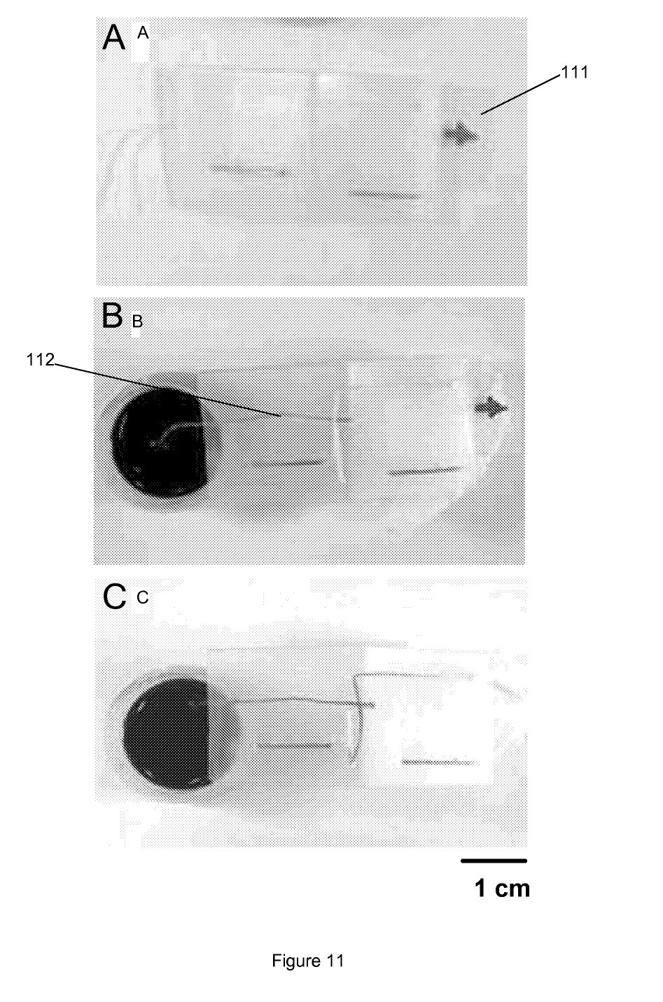

FIG. 11 shows a pull tab style switch adapted from a folding style switch. The pull-tab activated device is a simple adaptation of the folding style of on/off functional switches. Any device which is actuated by folding can be adapted to function by a pull tab.

The fold type switch detailed in example 8 above can be adapted to function with “pull-tab” style activation mechanisms. This is achieved by placing a small removable section of polymer film within the device, and then sealing the device permanently folded using adhesive, heat sealing or stapling. When the tab is removed by the user pulling upon it, threads on opposing sides of the device are brought into contact with each other and the switch is activated. An advantage of this method of actuation is its ease of use, as it eliminates the need for the user to hold the device folded shut, and minimises user contact with the internals of the device. Should an application require the incorporation of hazardous reagents, this switch enables them to be entirely enclosed within plastic films reducing the risk of user contact.

FIG. 11A shows an unused pull-tab switch before activation. The tab 111 can be identified by the arrow drawn on its end. The pull-tab switch shown in FIG. 11B has an inlet zone 112 loaded with ink solution. The pull-tab switch in FIG. 11C has had its tab removed to allow the flow of ink across the device.

The folding type switch can be adapted to a pull-tab switch by sizing a thin piece of polymer film to act as the tab. The tab needs to be large enough to cover the region where the opposing threads contacted each other, but small enough to allow staples or other items to seal the folded device permanently shut. The tab is then inserted into the device which is folded. Staples are driven through both sides of the far edge of the folded device parallel to the crease line, but do not penetrate the tab. Alternatively adhesive or heat sealing could be used as an alternative to stapling.

### Example 10

### Selective Flow Control Device

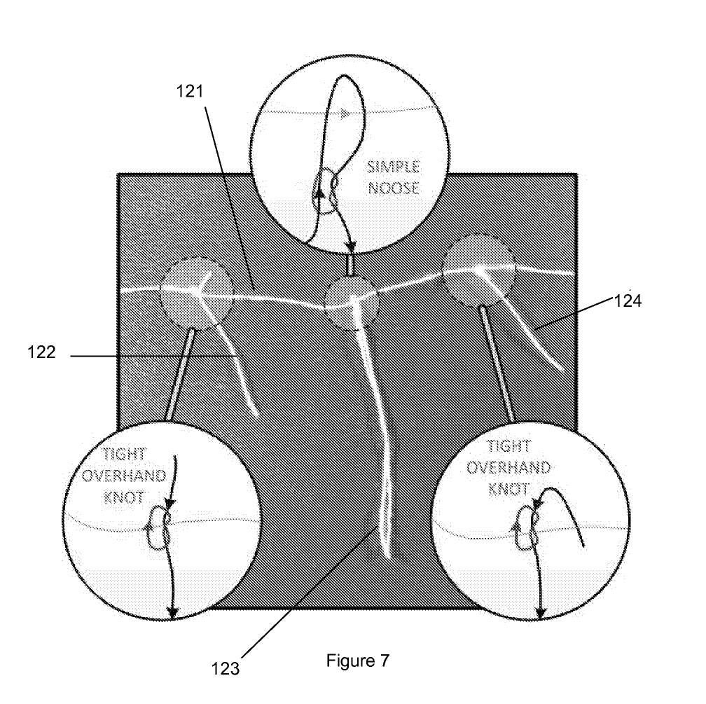

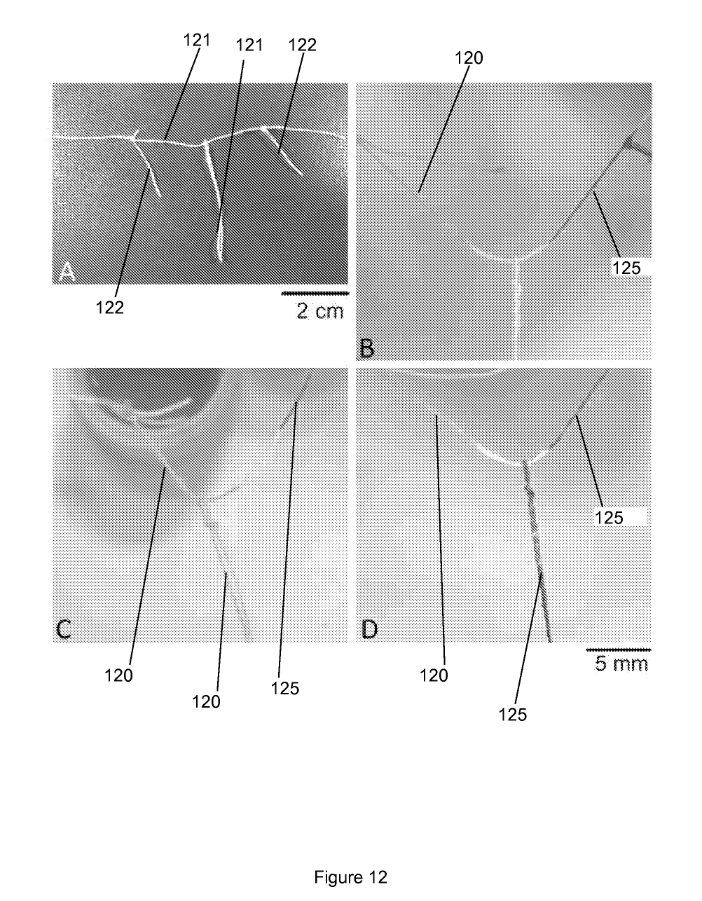

A selective flow control device according to an embodiment of the present invention can be made using only thread and adhesive. The device shown in FIG. 12 consists of two threads 121, 123 for conducting fluids and two support threads 122, 124 which are hydrophobic to allow handling. One of the hydrophilic threads 121 was tied to support threads at both ends using simple overhand knots, the topology of which is shown in FIG. 7. The centre of this conducting thread is then selectively blocked using adhesive, creating a 5 mm zone where ink flow can not penetrate. The second conducting thread 123 is then tied to the first 121 using a noose knot. The second conducting thread 123 can then be dragged along the first thread 121, and placed on the hydrophobic zone to render the device in the “off” position, also shown in FIG. 7.

The two way selector switch device shown in FIG. 12 allows a user to choose between two available samples or reagents, giving the ability to direct flow down a particular outlet channel at the time the user desires. FIG. 12A shows an unused selector switch set in the off position. FIG. 12B shows the selector switch in the off position but loaded with yellow 120 and cyan 125 inks. FIG. 12C shows the selector switch conducting ink flow of the yellow ink. When the user selects the flow of yellow ink, the yellow ink flows from the switch to the thread at the base of FIG. 12C. Similarly, when the user selects the flow of cyan ink, the cyan ink flows from the switch to the thread at the base of the switch as indicated in FIG. 12D. FIG. 12D shows the selector switch in the off position having previously carried the cyan ink.

Alternatively the device can function in reverse, with a single sample or reagent introduced to the lower channel, and the user selecting into which outlet they desire flow to be directed. Such a device is useful in complex systems which possess multiple reactor or detection sites, enabling users to selectively perform different types of analyses with the same device. An alternative design uses a combination of thread and a folding polymer film support. The user can select between different outlets by folding in different directions, or conversely select between different inlets with a single outlet.

### Example 11

### Flow Mixing Device

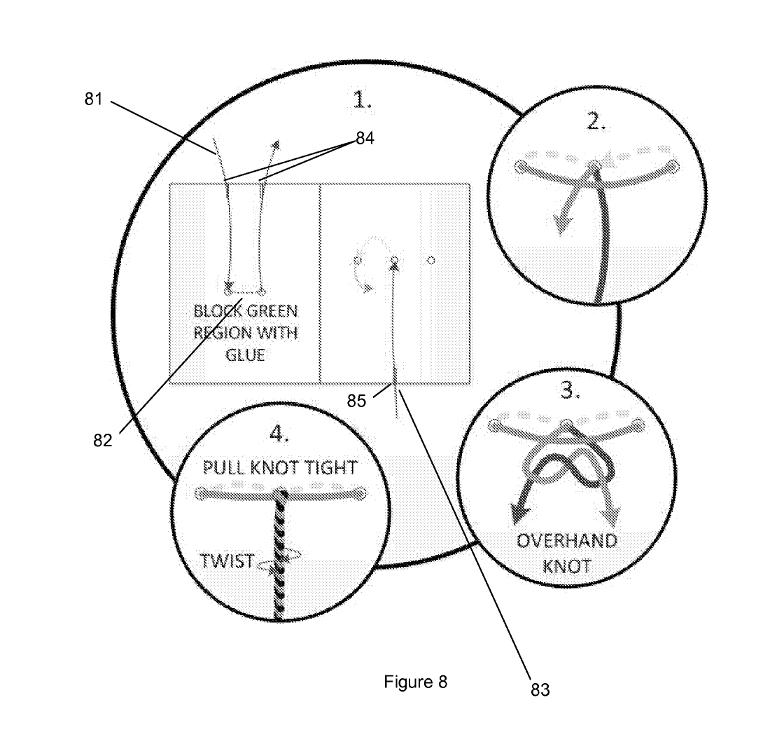

The ability to mix liquids is important for many applications. A flow mixer requires the most complicated construction process of the embodiments described. Beginning with a folded rectangular film identical to that described for the folding style switch above (example 8), five holes are punched through the film using a sewing needle. FIG. 8 describes the location of the holes and can be used as a template. The inlet thread 81 is then sewn into the two holes on the left, and the centre 82 blocked from flow with a small amount of adhesive, the ends of the thread are then secured in small slits 84 as shown. A second thread 83 is then sewn into the opposing side and tied as described by step 3 of FIG. 8. The final step (step 4) is twisting the two loose ends of the knot into one outlet channel, and securing the twisted threads into another small slit 85. Care must be taken during construction to ensure that the inlet and outlet threads are on the same side of the film.

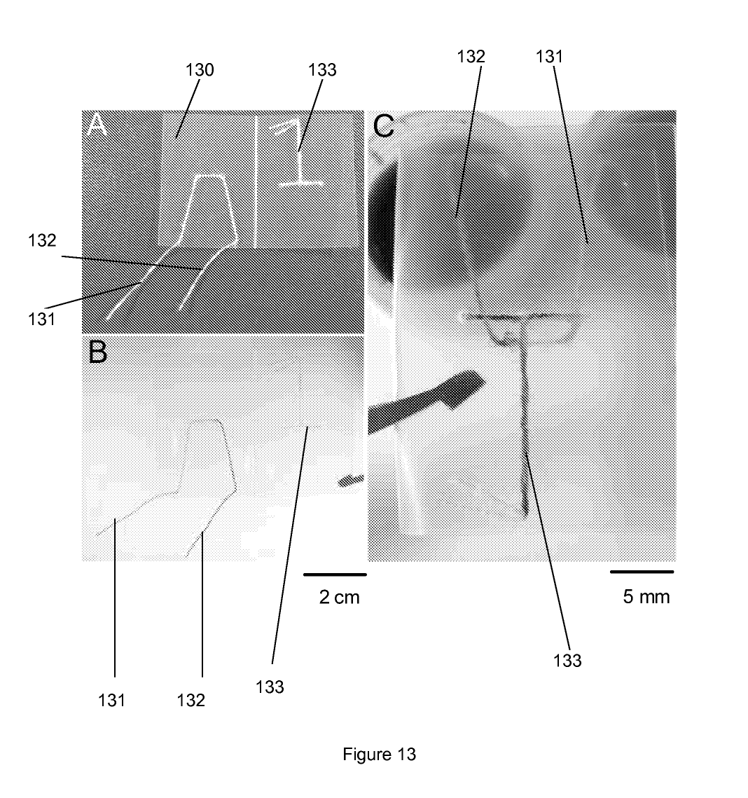

The embodiment of the present invention shown in FIG. 13 achieves excellent mixing of two coloured inks at the specific time desired by the user. Mixing occurs when the device 130 is folded bringing the two wet thread sections 131, 132 in contact with the mixing zone 133. In this case, the effectiveness of the mixer is illustrated in FIG. 13C by the vibrant green colour 133 which results from the mixing of cyan 132 and yellow 131 inkjet inks. This type of mixing switch is valuable for detection chemistries requiring two or more steps, with a sample being mixed with and then reacting with an initial reagent in a mixer, followed by further reactions with other reagents in subsequent mixers. Thread-based mixers can also be fabricated with “pull tab” or “sliding bead” activation mechanisms discussed in example 9.

### Applications

The above embodiments of the present invention can be used in various applications. Three examples of applications for the thread-based microfluidic devices are described below. Three sample solutions containing protein, glucose and a mixture of the two analytes were created.

### Reactor

Single switches can be built into the thread-based microfluidic devices to control the sequence and timing of fluid flow into the reaction zones. These devices can be used as low-cost and easy-to-use microfluidic reactors which are suitable for two/multi-step reactions. It is important to choose suitable materials as the reaction zone. Paper, threaded knots or cellulose powder have been shown to be viable options because of their porous structure and absorbent properties. In this application, textile was used as the reaction zone. Textile sheets can simply be cut into the desired shape to achieve well-defined reaction zones using scissors or a fabric guillotine.

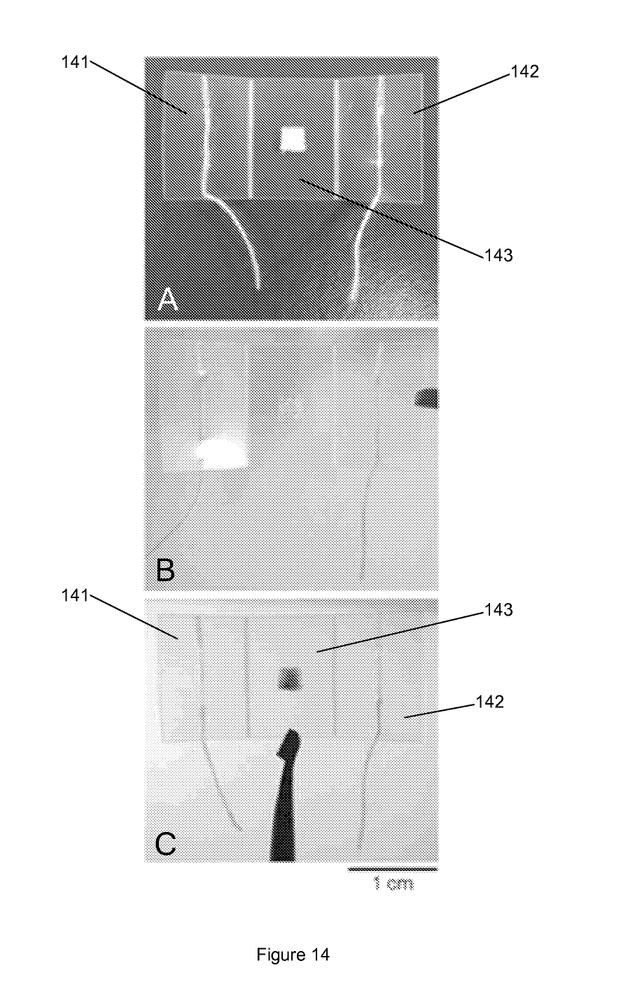

FIG. 14 displays a microfluidic reactor which uses a combination of two folding switches 141, 142 and a textile reaction zone (3×3 mm, secured using double sided tape). In this case a protein indicator was introduced first by activating the right switch, followed by a sample containing the protein analyte, in the left switch 141, being added to the reaction zone 143, resulting in the colour change shown in FIG. 14C. This design allows the user to “load” their own detection chemistries to create functional detectors, as well as execute multi-step reactions. The ends of the two inlet threads can be made to fixed lengths to control the intake quantities of the sample and indicator solutions.

### Two-Way Selector

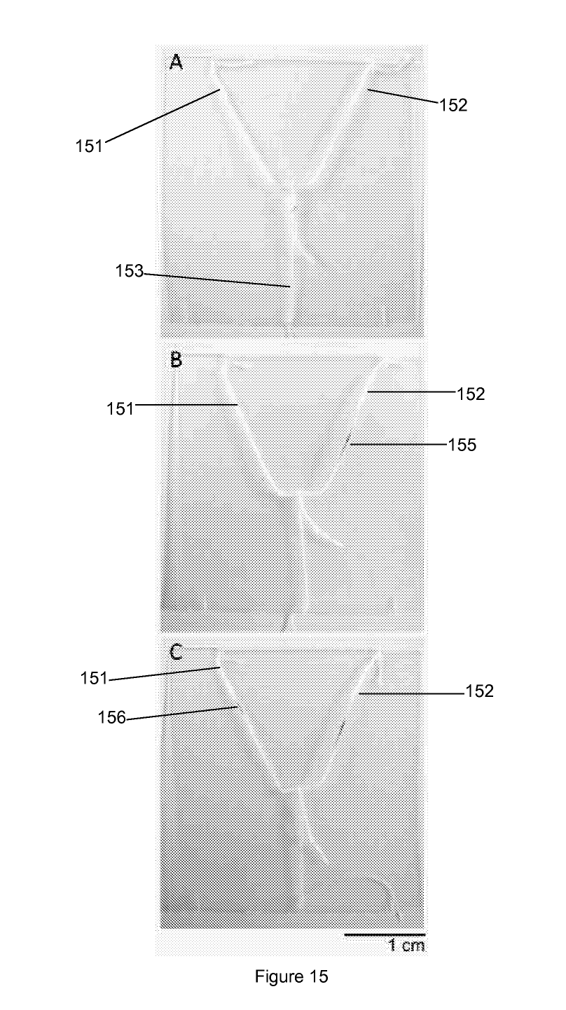

In another application of one of the embodiments of the present invention, thread can be fabricated into microfluidic devices which give selective control of liquid flow direction. With different device designs, two or more samples can be directed into one specified output port, or a single sample can be driven into different outlet channels. For example, a sample solution containing both glucose and protein was used to show one possibility of directing sample flow into different outlet channels, shown in FIG. 15. The glucose and protein indicators (0.1 μL) were deposited onto the upper left 151 and right 152 threads (i.e., the left and right outlet channels) respectively. The indicators were then allowed to dry under ambient conditions for 15 minutes. The sample solution was introduced from the lower thread 153 (i.e., the inlet channel). FIG. 15B shows that when the sample solution is selected to flow into the right outlet channel 152, by moving the loop to the right, the colour of the protein indicator changes from yellow to blue-green 155. This shows that the sample solution contained protein and had arrived at the desired channel. The loop is then moved to the left (FIG. 15C) to direct the sample flow into the left outlet channel 151. This is illustrated by the development of a yellowish brown colour 156 caused by the glucose indicator present. The results show that thread-based selectors are well suited for practical applications.

### Mixer

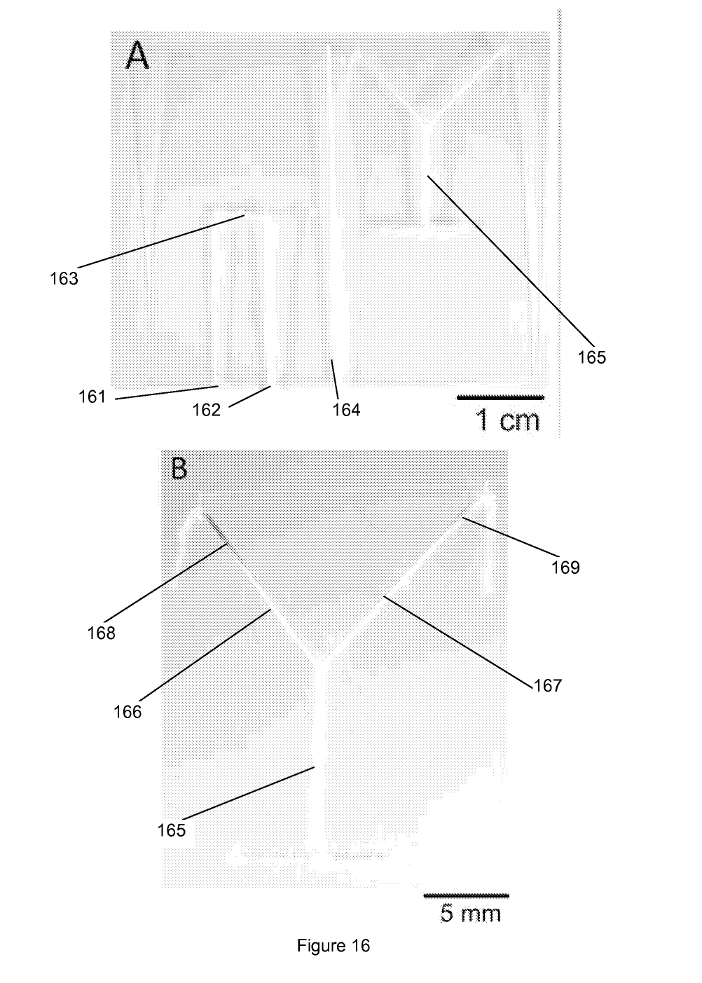

In yet another application of one of the embodiments of the present invention, the device shown in FIG. 16 mixed together two samples. The device then detects the two different biomarker analytes present (glucose and protein) in separate detection zones with the pre-loaded indicators to illustrate the mixing achieved. The two reagents entered the device on the left on different ends of a single thread 161, 162 which had a blocked region 163 to prevent premature mixing. Then the device was folded along the crease 164 to introduce the two sample solutions into the twisted threads 165 for mixing. Finally the mixed solution was split to two streams 166, 167 by dividing the twisted two threads. The protein and glucose indicator had already been deposited onto each end of the split left 166 and right 167 threads respectively. FIG. 16B shows samples containing protein and glucose being successfully mixed, with the two components detected separately after mixing, shown by colour change 168, 169.

1. A three-dimensional microfluidic system including:
at least one hydrophilic thread along which fluid can be transported through capillary wicking; and
at least one hydrophobic substrate for supporting the hydrophilic thread.

2. A three-dimensional microfluidic system according to claim 1 including a plurality of hydrophilic threads supported on the at least one hydrophobic substrate, wherein said threads are separate from each other.

3. A three-dimensional microfluidic system according to claim 1 including a plurality of hydrophilic threads supported on the at least one hydrophobic substrate, wherein at least one pair of said threads are in contact with each other.

4. A three-dimensional microfluidic system according to claim 1, wherein the hydrophobic substrate is a continuous film through which the hydrophilic thread is woven.

5. A three-dimensional microfluidic system according to claim 1, wherein the hydrophobic substrate is a woven sheet though which the hydrophilic thread is interwoven.

6. A three-dimensional microfluidic system according to claim 1, wherein the hydrophobic substrate is a hydrophobic thread about which a said hydrophilic thread is twisted.

7. A three-dimensional microfluidic system according to claim 1, wherein the hydrophobic substrate is a gel or wax for supporting the hydrophilic thread passing therethrough.

8. A three-dimensional microfluidic system according to claim 1, wherein the hydrophilic thread is formed from cellulose material.

9. A three-dimensional microfluidic system according to claim 1, wherein the hydrophilic thread is a formed from a continuous filament of hydrophilic material.

10. A three-dimensional microfluidic system according to claim 1, wherein the hydrophilic thread is a formed from a line of hydrophilic powder.

11. A three-dimensional microfluidic system according to claim 1, wherein the thread has a diameter of between 1 mm and 1 nm.

12. A three-dimensional microfluidic system according to claim 1, wherein the thread has a cross-section of variable diameter.

13. A three-dimensional microfluidic system including at least one hydrophobic thread supported on a hydrophilic substrate, wherein fluid is transported along the thread by capillary wicking.

14. A three-dimensional microfluidic system according to claim 1, further including a switch means for allowing or preventing fluid flow along the at least one hydrophilic thread.

15. A three-dimensional microfluidic system according to claim 14 wherein the switch means includes at least one hydrophobic segment on the at least one hydrophilic thread and means for bypassing the hydrophobic segment and allowing fluid flow.

16. A three-dimensional microfluidic system according to claim 15 wherein the bypass means includes a looped hydrophilic thread.

17. A three-dimensional microfluidic system according to claim 15 wherein the bypass means includes a bridging hydrophilic thread.

18. A three-dimensional microfluidic system according to claim 14 wherein the system includes a pair of hydrophilic threads and means for separating the threads and bringing the threads into contact to allow fluid flow from one said thread to the other said thread.

19. A method of transporting at least one fluid within a microfluidic system including at least one hydrophilic thread, including delivering the fluid to an end of the hydrophilic thread, the fluid being transported along the thread through capillary wicking.

20. A method according to claim 19 including transporting a plurality of fluids without mixing through the microfluidic system, including delivering each said fluid to a different hydrophilic thread, the threads being separate from each other.

21. A method according to claim 20 including transporting and mixing a plurality of fluids through the microfluidic system, including delivering each said fluid to a different hydrophilic thread, the threads being in contact with each other.

22. A method of detecting a fluid sample within a microfluidic system including at least one hydrophilic thread, including delivering said fluid sample to an end of the hydrophilic thread for transportation by capillary wicking therealong, at least part of the thread forming a sample detection zone.

23. A method of transporting and mixing a plurality of fluids within a microfluidic system including at least two hydrophilic threads and a hydrophobic substrate having at least two zones, each of the hydrophilic threads supported on a different hydrophobic substrate zone, including:
delivering each said fluid to a different hydrophilic thread; and
bringing the at least two hydrophilic threads into contact to cause mixing of the fluids.

24. A method according to claim 23 wherein the hydrophobic substrate zones are folded together bringing the at least two hydrophilic threads into contact.
